(19) United States
(12) Patent Application Publication
(10) Pub. No.: US 2016/0148917 A1
(43) Pub. Date: May 26, 2016

(54) COOLING DEVICE FOR ELECTRONIC COMPONENTS

(71) Applicant: National Chung-Shan Institute of Science and Technology, Taoyuan City (TW)

(72) Inventors: Yang-Kuo Kuo, Taoyuan City (TW); Chia-Yi Hsiang, Taoyuan City (TW); Hung-Tai Ku, Taoyuan City (TW)

(21) Appl. No.: 15/011,515

(22) Filed: Jan. 30, 2016

Related U.S. Application Data
(63) Continuation-in-part of application No. 13/708,990, filed on Dec. 8, 2012.

(51) Int. Cl. H01L 25/16; H01L 33/64; H01L 35/02

(52) U.S. Cl. CPC H01L 25/167; H01L 25/162; H01L 35/02; H01L 33/642

(57) ABSTRACT

A cooling device for electronic components is a combination of substrate (aluminum nitride substrate—thermoelectric elements—aluminum nitride substrate) and utilizing the temperature difference generated by two top and bottom ends of the cooling device to effectively remove the heat generated by the electronic components. This cooling device not only can effectively reduce temperature of the electronic components, but also store the power generated through its thermoelectric effect.

### BACKGROUND OF THE INVENTION

1. Field of the invention

The present invention relates to a cooling device for electronic components, and more particularly to a cooling device integrating a thermoelectric element with electronic elements.

2. Description of Related Art

That all electronic components generate heat is a natural phenomenon, which affects the lifespan and designed performance of the components. Therefore, a large number of solutions for this phenomenon are emerged, in particular, to reuse the heat generated by electronic components as a new energy, which becomes the subjects the R & D staffs specialize in.

Take light emitting diode (LED) for example, which is a daily use electronic component, having the advantages of environmental friendly, energy-saving, small size, high efficiency, long usage lifespan, etc. so that LED is widely used in daily life, such as LCD backlight, mobile phone backlight, signal lights, headlights, street lamps, art lighting, architectural lighting, and stage lighting control, home lighting, etc.

With the development of the LED industry and the increase of user need, the LED gradually reaches high-power, high-brightness and high-performance. However, a lot of heat generated by high-power LED can not be effectively dissipated, which results in high LED Junction Temperature, so that the LED brightness is reduced or even extinguished.

Because only about 15 to 20% electrical energy of the LED input power can be converted into light, nearly 80 to 85% electrical energy is converted into heat. If the heat generated by the LED light can not be dissipated, the LED Junction Temperature will be higher, which causes a qualitative change to the LED surrounding materials as phosphors and packaging plastic, and influences the LED luminous efficiency, stability and service life. Therefore, effective control of LED products' byproduct, heat, is a very significant issue.

Therefore, in addition to the heat dissipating effect of the heat sink is the primary design consideration, other factors such as the weight, size, appearance, convenience and application thereof and reuse of the energy released from the electronic components are still factors the industry needs to take into consideration.

In view of the drawbacks derived from the conventional technology, the inventor has tried hard to transform the heat energy generated by the electronic elements into a renewable energy. And the appearance, volume and weight of the invention are also considered at the same time. After years of research, a cooling device for electronic components is proposed in the present invention so as to solve the above-mentioned problems. The present invention is described below.

The invention, as well as its many advantages, may be further understood by the following detailed description and drawings.

### SUMMARY OF THE INVENTION

The primary objective of the present invention is to provide a cooling device for electronic components, which effectively resolves the heat dissipation problem encountered in the operation of the conventional electronic components, and achieves the goal of extending usage lifespan, weight and size reducing, and the appearance aesthetic design.

A further objective of the present invention is to transform the heat generated by the electronic components in operation into a renewable energy by using the temperature difference of thermoelectric effect, and the energy is to be stored in battery as a spare power.

In order to achieve the above mentioned objective, the present invention provides a cooling device for electronic components, including: a first substrate, at least one electronic element, a thermoelectric element, a second substrate, a heat sink fin, and a battery. Wherein, the first substrate is configured as having a metallized circuit, and is provided with a first surface and a second surface. The at least one electronic element is disposed on and electrically connected to the metallized circuit on the first surface of the first substrate. The thermoelectric element is configured on the second surface of the first substrate so as to conduct the heat generated by the at least one electronic element. The second substrate is provided with a third surface and a fourth surface, the third surface of the second substrate is coupled to the thermoelectric element, so as to conduct the heat to the fourth surface. The heat sink fin is disposed on the fourth surface of the second substrate to conduct heat, and is made of heat conductive metal such as aluminum. The battery is coupled between the first substrate and the second substrate for storing energy generated by the cooling device, wherein a thermoelectric effect is produced by thermal temperature differences between the first substrate and the second substrate. Wherein the first substrate and the second substrate are made of an insulating ceramic material selected from one of the following group consisting of: alumina and aluminum nitride.

Preferably, the at least one electronic element is one selected from the following group consisting of: an LED, a CPU and a solar focusing device.

Preferably, the thermoelectric element includes: a first conductive layer including a plurality of first electrodes, configured on the second surface of the first substrate; a second conductive layer comprising a plurality of second electrodes, configured on the third surface of the second substrate; and a plurality of N-type semiconductors and a plurality of P-type semiconductors, wherein the plurality of N-type semiconductors and the plurality of P-type semiconductors are alternatively configured between the plurality of first electrodes and the plurality of second electrodes, and are coupled to the plurality of first electrodes and the plurality of second electrodes so as to form a current loop.

Preferably, the first surface of the first substrate is a cooling surface.

Preferably, the first surface of the first substrate is a heating surface.

The technical characteristics and operation processes of the present invention will become apparent with the detailed description of preferred embodiments and the illustration of related drawings as follows.

### BRIEF DESCRIPTION OF THE DRAWINGS

FIG. 1 is a schematic diagram of a cooling device for electronic components according to a preferred embodiment of the present invention;

FIG. 2 is a perspective view of a cooling device for electronic components according to a preferred embodiment of the present invention; and

FIG. 3 is a schematic view showing placement of various elements of a cooling device for electronic components according to a preferred embodiment of the present invention.

### DETAILED DESCRIPTION OF THE INVENTION

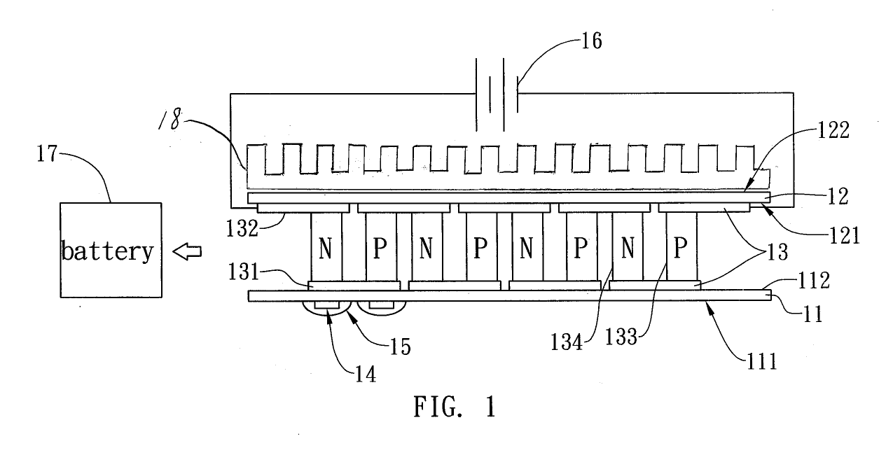

Refer to FIG. 1 for a schematic diagram of a cooling device for electronic components according to a preferred embodiment of the present invention. As shown in FIG. 1, the present invention utilizes the temperature difference of the cooling chip to be applied to the cooling device of the electronic components. This embodiment uses an LED element as the electronic element. The heat generated by the LED chip is sent to the cooling chip to reduce the temperature of the LED. This design can also be proved to greatly reduce the LED overall size and weight.

The cooling device of this embodiment includes: a first substrate 11, at least one electronic element 14, 15, a thermoelectric element 13, a second substrate 12, a heat sink fin 18, and a battery 17. Wherein, the first substrate 11 is configured to contain a metallized circuit, and having a first surface 111 and a second surface 112. The at least one electronic element 14, 15 being LED chip 14 and LED lens 15 respectively, is configured on the first surface 111 of the first substrate 11 and coupled to the metallized circuit. The thermoelectric element 13 is configured on the second surface 112 of the first substrate 11, to conduct the heat generated by the at least one electronic element 14, 15. The second substrate 12 is provided with a third surface 121 and a fourth surface 122, with the third surface 121 of the second substrate 12 coupled to the thermoelectric element 13, to conduct the heat to the fourth surface 122. The heat sink fin 18 is disposed on the fourth surface 122 of the second substrate 12 to conduct heat, and is made of heat conductive metal such as aluminum, but the present invention is not limited to this. The battery 17 is coupled between the first substrate 11 and the second substrate 12 for storing energy generated by the cooling device, wherein a current is generated by temperature differences between the two substrates through thermoelectric effect. The first substrate 11 and the second substrate 12 are made of an insulating ceramic material and selected from one of the following group consisting of: alumina and aluminum nitride.

In the descriptions above, the thermoelectric element 13 includes: a first conductive layer including a plurality of first electrodes 131, configured on the second surface 112 of the first substrate 11; a second conductive layer including a plurality of second electrodes 132, configured on the third surface 121 of the second substrate 12; a plurality of N-type semiconductors 134; and a plurality of P-type semiconductors 133. Wherein the plurality of N-type semiconductors 134 and the plurality of P-type semiconductors 133 are alternatively configured between the plurality of first electrodes 131 and the plurality of second electrodes 132, and are coupled to the plurality of first electrodes 131 and the plurality of second electrodes 132 to form a current loop.

The technical idea of the present embodiment is to combine a thermoelectric cooling chip (Bi2-Te3) with the semiconductor elements 133, 134, electrodes 131,132 and the substrates 11, 12 into a cooling device by using the principle of thermoelectric effect.

When the current is input into the cooling device, heat can be transferred by the cooling device from one end (N→P endothermic, cold end, as the third surface 121 on the first substrate 11) to the other end (P→N exothermic, hot end, as the fourth surface 122 on the second substrate 12), to form a temperature difference phenomenon between a hot side and a cold side of the cooling device. The greater the input current is, the greater the temperature difference will be. The maximum temperature difference of the best finished product has been up to 74° C.

The greater the temperature difference between the hot side and the cold side of the cooling device is, the greater the electric energy generated by the thermoelectric effect is. So that the cooling device further has a battery 17 used to store the electric energy of thermoelectric effect generated by the temperature difference between the first substrate 11 and the second substrate 12 of the cooling device.

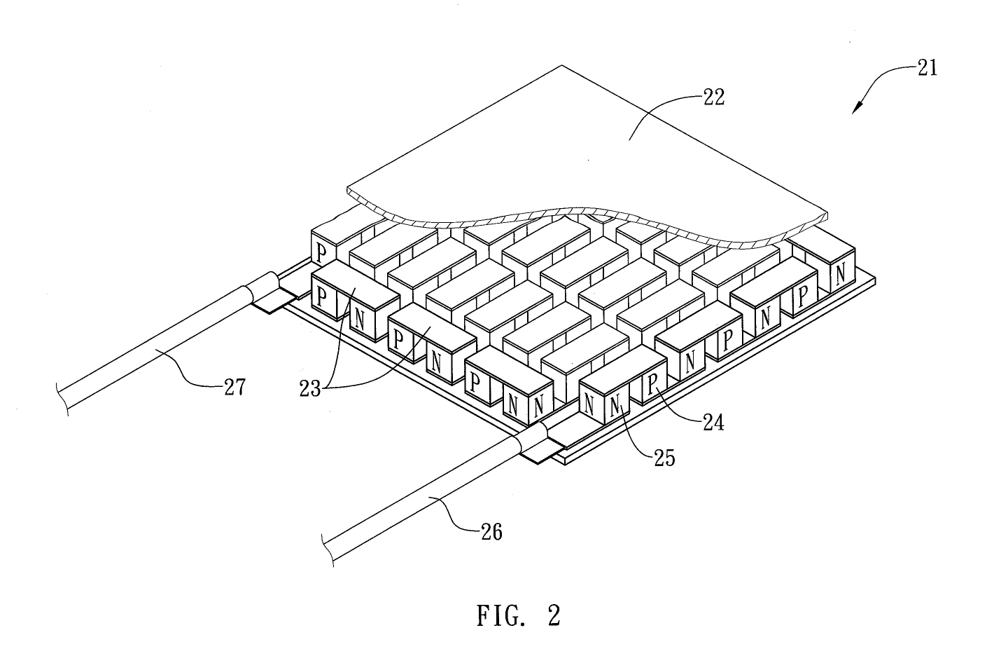

Refer to FIG. 2 for a perspective view of a cooling device for electronic components according to a preferred embodiment of the present invention. As shown in FIG. 2, a dielectric substrate 22 is each coated on the upper and lower layers of the cooling device 21. Between the dielectric substrates 22, a plurality of N-type semiconductors 24 and P-type semiconductors 25 are coated by two layers of plural conductors 23, wherein the plurality of N-type semiconductors 25 and the plurality of P-type semiconductors 24 are alternatively configured between the two layers of plural conductors 23, and coupled to the upper and lower electrodes formed by the two layers of plural conductors 23, so as to form a current loop.

As such, the direction of current applied to the cooling device 21 can be controlled to cause a cold end on the upper side of the cooling device 21 and to cause a hot end on the lower side of the cooling device 21, so as to conduct the heat.

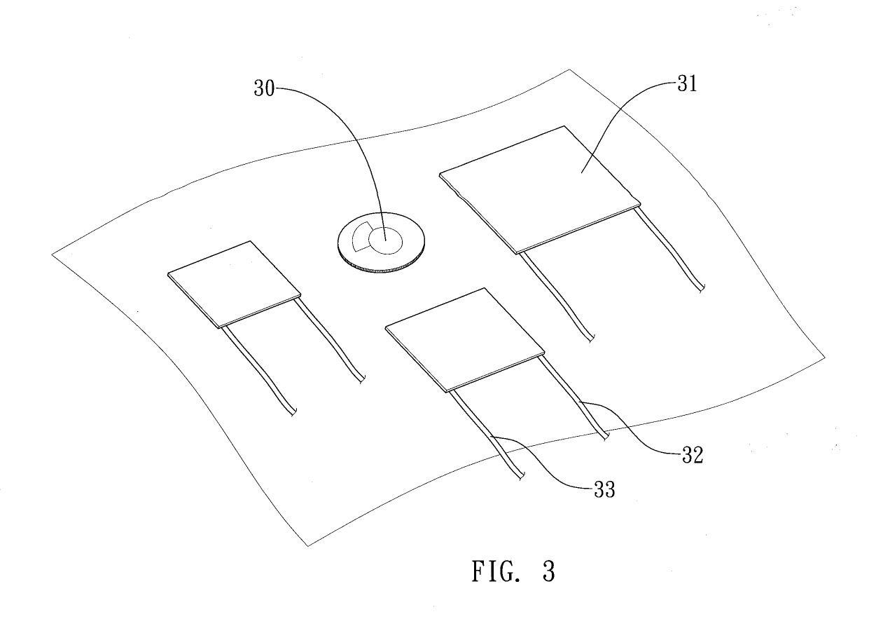

Refer to FIG. 3 for a schematic view showing placement of various elements of a cooling device for electronic components according to a preferred embodiment of the present invention. As shown in FIG. 3, the size of the cooling device 31 of the present invention is small, equivalent to a coin of NT ten dollars 30. Each cooling device 31 includes a cathode pin 32 and a negative pin 33 to connect the power source 16 as shown in FIG. 1.

In summary, the cooling device of the present invention has high cooling efficiency to indirectly extend the lifespan of the configured components, it also has the characteristics of small size, light weight, long life, high reliability, environmentally friendly (without using refrigerant), easy maintenance, and energy reuse. Therefore, the cooling device of the present invention is suitable for use as heat dissipation of electronic components and has a good prospect on the market.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A cooling device for electronic components, comprising:
a first substrate having a first surface and a second surface, a metallized circuit being disposed on the first surface;
at least one LED disposed on and electrically connected to the metallized circuit on the first surface of the first substrate;
a thermoelectric element configured on the second surface of the first substrate so as to conduct heat generated by the at least one LED;
a second substrate having a third surface and a fourth surface, the third surface of the second substrate coupled to the thermoelectric element so as to conduct heat to the fourth surface;
a heat sink fin, disposed on the fourth surface of the second substrate to dissipate heat; and
a battery coupled between the first substrate and the second substrate for storing energy generated by the cooling device,
wherein the thermoelectric element comprises:
a first conductive layer comprising a plurality of first electrodes, configured on the second surface of the first substrate;
a second conductive layer comprising a plurality of second electrodes, configured on the third surface of the second substrate;
wherein the first substrate and the second substrate are made of an insulating ceramic material selected from one of the following group consisting of: alumina and aluminum nitride;
wherein a greater a temperature difference between the first substrate and the second substrate is, a greater electric energy is so generated, and a maximum temperature difference between the first substrate and the second substrate is 74° C.; and
wherein the thermoelectric element further comprises:
a plurality of N-type semiconductors and a plurality of P-type semiconductors, wherein the plurality of N-type semiconductors and the plurality of P-type semiconductors are alternatively configured between the plurality of first electrodes and the plurality of second electrodes, and are coupled to the plurality of first electrodes and the plurality of second electrodes so as to form a current loop;
wherein each LED has an LED chip, and each LED chip is disposed on the metallized circuit and is corresponding to each N-type semiconductor or each P-type semiconductor.

2. The cooling device as recited in claim 1, wherein the first surface of the first substrate is a cooling surface.
